(19) United States
(12) Patent Application Publication
(10) Pub. No.: US 2005/0156282 A1
(43) Pub. Date: Jul. 21, 2005

(54) Semiconductor device and method of its manufacture

(76) Inventor: Yoram Palti, Haifa (IL)

Correspondence Address: NATH & ASSOCIATES, 1030 15th STREET, NW, 6TH FLOOR, WASHINGTON, DC, 20005, US

(21) Appl. No.: 10/811,301

(22) Filed: Mar. 29, 2004

Related U.S. Application Data
(60) Provisional application No. 60/535,824, filed on Jan. 13, 2004.

(51) Int. Cl. H01L 29/06

(52) U.S. Cl. 257/618

(57) ABSTRACT

An integrated semiconductor device and method for its manufacturing are presented. A semiconductor element is provided having a perforation extending along a central axis of the element, thereby defining a central channel inside said element. An inner surface of the perforation is processed via the central channel to define features of the semiconductor device to be manufactured.

### FIELD OF THE INVENTION

This invention relates to semiconductor devices and method of manufacturing such devices.

### BACKGROUND OF THE INVENTION

In accordance with the existing technology, semiconductor devices (microchips) are planar, basically rectangular units containing multiple electronic elements (logic switches, gates, etc.) and circuitry often arranged in multiple layers. The microchips are manufactured in a very elaborate multi-stage process on semiconductor wafers, typically thin silicone discs of 10-20 cm in diameter. A wafer structure usually contains numerous small discrete electronic units (chips), many or all of which are identical. Unit size may be about 0.1-1.0 cm². Thus, a wafer structure may contain hundreds to thousands of individual electronic units.

The main processes involved in the chip manufacture are as follows: lithography, wet processing, washing, rinsing, etc.; thermal processing; Chemical Vapor Deposition (CVD); Physical Vapor Deposition (PVD); Plasma Processing; Ion Implantation; Chemical Mechanical Polishing (CMP); Wafer Grinding. These processes are carried out by means of numerous highly complex and expensive machines. All of these processes are usually sequentially applied to the wafer surface. The manufacturing often involves manual or automatic transportation of a number of wafers from one site, where a specific process is being carried out, to the next site. A typical total processing time for a wafer may be in the order of 30 days, or more when critical pieces of equipment are overloaded.

According to the conventional technique, microchips are manufactured in a “clean room” environment on one of the two surfaces of a wafer, which is a thin flat disk-like slab of silicon. The manufacture includes grinding, etching, washing, spinning, coating, un-coating, cleaning, etc. that are all carried out on the large wafer surface. These processes generate dirt-dust particles and are highly susceptible to contamination by such particles as well as ones originating from the environment and workforce. Moreover, the wafers are frequently transported from one machine to the other. Therefore, to avoid damage by “dust” to the wafer emerging components, all these manufacturing processes are carried out in high grade clean rooms.

One of the basic critical, time consuming processes, requiring extremely high accuracy (that determines the quality of the product) and very expensive machinery is the lithography. This process involves very accurate optic compression of computer drawn schemes that describe the circuitry and other elements to be manufactured in each manufacturing layer of the wafer. A full process may require up to 25 such schemes. These large scale drawings are down scaled by very accurate optic systems and etched for example on opaque glass plates, each roughly the size of the wafer-masks. Each mask is placed at a precise location on a wafer coated by a photosensitive or “photo-resist” material while a laser beam scans the whole wafer surface reaching, through the mask, only those areas that are to take part in the current process. This maneuver is repeated numerous times with different masks. In the chip development process when an error is found in the circuitry, new masks have to be manufactured and the placing and scanning process repeated. For mass producing wafers, either numerous sets of masks are manufactured or the processing is carried out in series.

In between many of the different processes that the conventional microchip undergoes the entire batch of wafers has to be thoroughly washed. This is done by transporting the batch to a washing bath where agitation and chemicals are used. This action is repeated numerous times and may require a series of baths with different solutions. On the whole this is time consuming and requires large volumes of chemicals, etc.

Several techniques have been developed aimed at replacing a flat conventional chip, which are disclosed for example in the following patents.

U.S. Pat. Nos. 5,955,776 and 6,245,630 disclose a spherical shaped semiconductor integrated circuit (“ball”) and a system and method for manufacturing same. The ball replaces the function of the flat, conventional chip. The physical dimensions of the ball allow it to be adapted to many different manufacturing processes which otherwise could not be used. Furthermore, the assembly and mounting of the ball may facilitate efficient use of the semiconductor as well as circuit board space.

U.S. Pat. No. 6,509,645 discloses a spherical semiconductor device including a spherical semiconductor element having one or more electrodes on its surface. Spherical conductive bumps are formed at the positions of the electrodes. The electrodes are so arranged as to contact a common plane. Spherical bumps constituting a group to be connected to the outside protrude above the spherical semiconductor element such that a predetermined gap is formed between a plane or a spherical surface capable of contacting the spherical bumps and the surface of the spherical semiconductor element. The spherical semiconductor device is connected to various circuit boards or another semiconductor device through the spherical bumps. This affords easy and accurate electrical connections to the outside.

U.S. Pat. Nos. 5,270,485 and 5,767,824 disclose a three-dimensional circuit structure including a plurality of elongate cylindrical substrates positioned in parallel and in contact with one another. Electrical components are formed on the surfaces of the substrates, along with electrical conductors coupled to those components. The conductors are selectively positioned on each substrate so as to contact conductors on adjacent substrates to allow for the transfer of electrical signals between substrates. The conductor patterns on the substrates may be helical, circumferential, or longitudinal, in such a fashion that substrates may be added to or removed from the bundle so that the bundle will continue to operate as needed. The cylindrical nature of the substrates leaves gaps or channels between the substrates to which cooling fluid may be supplied for cooling the circuitry.

### SUMMARY OF THE INVENTION

There is a need in the art to facilitate manufacture of semiconductor devices by providing a novel manufacturing method which provides for reducing the features' size (the co-called “critical dimensions”), eliminating the need for or at least significantly reducing the “clean room” requirements, and eliminating the need for using a mask in a lithography process. There is also a need for a chip manufacturing technique simplifying the vacuum-based layer deposition process (CVD or PVD), as well as providing a simpler and more accurate means for delivering controlling and changing fluids associated with various fabrication processes and providing better means for mechano-chemical polishing.

The present invention solves the above problems by manufacturing semiconductor devices by means of making a perforation (through going opening) in a semiconductor element to define a central channel, and processing the inner surface of the opening via this central channel. Elements (features) of the semiconductor device are thus arranged on the inner surface of the perforated semiconductor element.

Such a perforation (through going opening) in the semiconductor element preferably has a circular cross section, and the semiconductor element preferably has a tubular-like or ring-like geometry. It should however be understood that any other geometry of a perforated semiconductor element may be used. Thus, for simplicity, the semiconductor element will be referred to hereinbelow as a “ring-like” or “tube-like” element, and a semiconductor device fabricated on such a perforated semiconductor element will be referred to as an “annular chip”.

Thus, according to one broad aspect of the present invention, there is provided a method for manufacturing an integrated semiconductor device, the method comprising: providing a semiconductor element having a perforation extending along a central axis of said element, thereby defining a central channel inside said element; and processing an inner surface of said perforation via the central channel to form features of the semiconductor device to be manufactured on said inner surface.

Generally, the semiconductor element may be a single ring-like, perforated disk like, or elongated tube-like element. Preferably, the present invention utilizes formation of individual micro-chips on individual mini-wafers shaped like a ring or perforated disk and arranged in a stack one on top of the other to form a column with a central channel, which is a continuous hermetically sealed channel running from one end to the other. The micro-chips (features of semiconductor device) are fabricated on the inner surface of the perforation. The central channel serves for introducing various agents that are washed through, coat, act on, etch, implanted in, etc. and/or for introducing probes designed to perform various tasks in the fabrication process. The annular chips can be stacked to form a complete circuitry, or perforated semiconductor elements may be stacked and then processed together to form a complete circuitry.

According to yet another broad aspect of the present invention, there is provided an integrated semiconductor device comprising a semiconductor element having a perforation extending along a central axis of said element, an inner surface of said perforation being patterned in accordance with features of the semiconductor device.

According to yet another broad aspect of the invention, there is provided an integrated semiconductor device comprising a ring-like semiconductor element, an inner surface of said ring-like element being patterned in accordance with features of the semiconductor device.

The present invention in its another broad aspect provides an electronic circuit comprising a stack of ring-like semiconductor elements aligned along a central axis of the stack, an inner surface of the stack being patterned in accordance with features of the electronic circuit.

According to yet another aspect of the invention, there is provided an integrated circuit comprising a semiconductor structure in the form of a plurality of perforated semiconductor elements arranged such that the perforations in the elements are aligned along an axis of the stack thereby defining a common perforation extending along the stack, an inner surface of said common perforation being patterned in accordance with features of the integrated circuit.

According to yet another broad aspect of the invention, there is provided a method of manufacturing a ring-like semiconductor device, the method comprising providing a ring-like semiconductor element; and applying a lithography process to an inner surface of the ring like semiconductor element.

Since according to the technique of the present invention all the processes of the annular chip based manufacture are carried out in the hermetically sealed central channel of each annular chip stack, “dust” from the environment can not reach the active surfaces, and “dust” generated by the processing itself can be very effectively washed away and disposed off by flowing liquid or gas through the central channel. This significantly reduces the required level of room cleanliness. The small size of the annular chip relative to that of a flat wafer makes the far less fragile than thinned wafers.

The annular chip is formed using “virtual” lithography and “soft” masks. This is implemented by using direct photo-lithography by means of a central probe and without the use of masks. Rather, a computer controlled one or more laser or another light source beam(s) is used to shine light only at the desired locations on the annular chip surfaces. The central channel is coated by required materials (photoresist, etc.). The central probe is positioned in the central channel.

The central probe is basically configured for allowing passage of processing medium therethrough, wherein the processing medium may be liquid, gas, or certain radiation (light, charged particles' beam, X-ray). It should be understood that the term “processing” refers also to monitoring (metrology, inspection). The central probe may carry a plurality of radiating elements arranged in a spaced-apart relationship along the probe, thus enabling processing a plurality of locations, respectively, on the inner surface of the semiconductor element. Such a probe may be a light conduit (single or multiple channel), such as an optic fiber, capable of transmitting visible and/or UV radiation, and may have a special cladding with perforations or “spots” that do not reflect back the light that reaches them. These perforations or spots constitute the radiating elements. Thus, when the central probe carries light, a beam of light is emitted from this spot. The size of the spot can be very small, for example, a perforation made by a focused laser beam can be 1 micron or less. When the diameter of the central probe is close to that of the central channel, the illuminated spot size on the inner surface of the annular chip is as small as the spot, i.e., in the order of one micron. Spots are made along a line running along the central probe at distances equal to the distance between corresponding points on adjacent annular chips in the stack. Thus, when the central probe is positioned at its initial location, the spots illuminate corresponding “initial” points on all the annular chips in the stack. The central probe can be rotated rapidly along its axis relative to the annular chip stack.

Alternatively, or additionally, patterning by illumination can be implemented by means of an elongated tube filled with gas, such as xenon, that is electrically excited to generate light throughout the length of the central channel, and designing the tube so as to enable light exiting the tube at predetermined location(s). Such illuminating devices are also known to produce UV and extreme UV (EUV) that can provide better optic resolution essential to reduce the size of the micro-circuitry.

Such a light conduit may include a plurality of fibers with distal ends of the fibers being arranged in the spaced-apart relationship, thus presenting the plurality of spaced-apart radiating elements. In this case, light directing elements are preferably accommodated at the distal ends, respectively, to 90 degree rotate the light beams, respectively, and thereby direct them towards the inner surface.

It should be understood that the technique of the present invention utilizes direct near field illumination, and therefore the need for elaborate lens that can not be made out of glass, that does not transmit deep UV, is alleviated or made minimal. The illumination system preferably includes such light directing means capable of reducing the diameter of a light beam impinging onto the surface. This is implemented by utilizing an annular aperture arrangement, e.g., configured as a pinhole or a short tube or a corresponding diameter, accommodated in the optical path of a light beam propagating from the radiating element of the probe towards the inner surface of the perforated semiconductor structure. The illumination system is preferably configured for producing polarized light, preferably radially polarized light. The spot size can generally be of about 0.2 square angstroms.

When optic fibers are used, the illumination source (radiating element) can be separated by a small gap from the light conduit that is equipped with a proper optic coupler to allow for spinning of the light conduit. Alternatively the annular chip can spin around a stationary central probe. If illuminated constantly, as it rotates the central probe illuminates a line on the all corresponding locations in the stacked annular chips. If the central probe illumination is in pulses, the annular chip illumination will be in spots, the size of which is determined by the spot diameter, the flash duration and speed of rotation. Thus, at a given speed of rotation, that can be computer controlled, by computer controlled flashing one can “draw” any illumination pattern along the line on the annular chip. After completing a full “illuminating” rotation, the central probe is pulled-pushed by a selected step to the next position to be acted upon on the annular chip and the rotation-flashing process is repeated. This process is repeated until all the necessary annular chip area (covered by photoresist, etc.) is illuminated, as if it was illuminated through a mask.

As indicated above, the spot size can be of about 1 micron or even lower. The central probe can be moved up and down along its axis by a motorized micromanipulator with a resolution better than 0.1 micron. Alternatively, the stack of annular chips can be moved up and down along its long axis relative to the central probe. Therefore, the system resolution can be in the order of 0.01-0.1 micron. As the spot writing is virtually of contact print nature, it may be possible to achieve resolutions better than 1 micron. The resolution may be improved by using a pinhole in the near field illumination mode, thus reducing the spot size to 1 nm and less. It should also be noted that the duration of this “virtual” lithography process can be significantly shorter than the conventional one.

In the annular chip manufacturing, all the processes involving the use of fluids—liquids, or gases, that make contact with the chip are carried out by the flow of the fluid in the central channel. In this case, the stack is stationary while the fluids can be changed by switching of flows, etc. Rapid flow rates can be very effective in cleaning. Saving in quantities of required chemicals, etc. can be significant due to the relatively small volumes needed, in contrast to the conventional baths, and can be further increased by circulation (recycling) and possibly filtration. Drying can be achieved by either flushing air or gas or creating vacuum in the central channel. It is much easier and quicker to create vacuum in the small volume central channel tubing.

Thermal processing, which is conventionally carried out by placing wafers in ovens, can be adopted in the annular chip fabrication. However, an alternate mode of fast and simple heating would be by means of the flow of gas or liquid through the central channel. The flow can be in the central channel itself, or through a metal tube running along the central channel. Efficient cooling can also be achieved in a similar manner. Heating can also be achieved by an electric conducting heating wire running along the axis of the central channel.

The layer deposition processes (CVD and PVD) are simplified with the annular chip structure of the present invention, due to the use of flow through the central channel. Plasma processing can also be made in the central channel. This is because vacuum or gas atmosphere are both very easy to implement, and the technique may be very effective as plasma is generated in much smaller volumes as compared to the current fabrication technologies.

For ion implantation, a tubular structure requires that an electric field be created between a central wire or core and the annulus. This creates an axial symmetric field which would be very homogeneous with regards to the annular chip surface.

Chemical Mechanical Polishing (CMP), which consists of flatting the wafer's surface; is implemented either by depositing of additional material and back polishing it, or by depositing and reflowing heavy doped SiO₂, or by depositing thick resist layer. Current fabrications achieve material deposition by a variety of ways: spraying, dipping, etc. Often coating is aided by spinning that gives controlled thin layers. In the annular chip fabrication, all these processes can be used, but spinning becomes more complex: the stack has to spin on an axis normal to its long axis. Addition of spinning on its long axis will improve the results. It should be noted that coating can be improved here by flushing fluid along the central channel to remove the excess material.

The wafer grinding-polishing can be effectively implemented in the annular chip fabrication. The conventional rotating polishing discs, etc., that are used to grind the wafer surface, are replaced in the annular chip fabrication by a rotating cylindrical or conical polishing-grinding probe that is introduced into the central channel and moved along its axis. This is a very effective and accurate processing mode. Different thicknesses can be achieved by using probes of different sizes instead of controlling the depth of movement of the planar grinder. The annular chip polishing-grinding can be more easily coupled with liquid cleaner or lubricant and liquid or gas cooling. Also, as with other operations, all particles generated are effectively washed away. It should be noted that in order to achieve high accuracy, the grinding cylinder has to be held at both its ends. Enhanced accuracy can be achieved as the distances from the rotation axis are normally much smaller for the central probe as compared with the conventional flat surface polishing disks.

Due to the fact that in the annular chip fabrication the conventional wafer is broken into numerous elements makes it possible to at least partly eliminate a need for conventional bonding. When each annular chip is a separate chip, the silicon ring it is formed on can be prepared with both contact pads on its outer surface (or any other surface) with leads leading to pre-selected points on the active annular chip surface. The leads can be manufactured on the surface by conventional means including printed circuit methods and standard microelectronics. The annular chip construction will make the proper contacts with these leads.

Annular chips can be packaged as conventional rectangular electronic components replacing the regular chips within them and thus be incorporated in standard boards in the construction of devices. However, they can maintain their annular shape, i.e. have a very different geometry; and integrated together as a stack. These annular chips would have their contact pads on either their upper and lower flat surfaces, or on their periphery (outer circumference). The former can also be in the form of conducting perforations and rods that can make direct annular chip to annular chip contacts in a stack. Preferably, such chip-to-chip contacts are made by means of connecting rings. These elements have selected connections between their pads or conducting perforations so that the proper circuitry is achieved. Leads can run on the outer surface of the annular chip, so as to have long connections in a stack of components.

While regular cuboid electronic components can not be stacked due to cooling consideration, a device formed by stacked annular chips can be very effectively cooled by flow of air or even liquid. The periphery of the annular chip ring can include conducting leads such that continuous lines run along the whole length of the stack. A typical annular chip may hold over 100 leads. The connection between these leads and the chip can be made by prefabricated or specially designed connecting rings (connecting annular chip). Wiring may be more efficient, lines do not cross, and with the help of connecting rings (between annular chips) and shifting rings (from one position to another) one may not need the use of tailor made printed circuits. The closed structure plus circular conducting screens are good against pickup of noise and electromagnetic irradiation. Per volume, annular chip stacks hold 2-3 times more chip surface area, as compared with the conventional micro-chips built on boards.

Thus, the technique of the present invention provides for minimizing the need for high grade clean rooms. Almost all activities can be made at one site/location: instead of moving the wafers from one machine to another (chemical baths, wash, coat, lithography, etc), all agents are directed to the annular chip stack via liquid or gas flow control and the central probe. The number and complexity of processing machines may be much smaller and throughput higher. The volumes of chemical agents, gases, fluids, etc. needed for processing are much smaller. Constant agent flows can be used, thus providing an advantage in some types of chemical and other process. With the present invention, the expensive, complex multi-stage photolithography is much simpler and can be implemented using much cheaper equipment. The Virtual Lithography as well as other processes can be much shorter. Photolithographic mask errors can be corrected practically on line (Soft Masks). Bonding and its machinery can possibly be eliminated.

Thus, according to yet another broad aspect of the invention, there is provided a probe for use in manufacturing a semiconductor device on an inner surface of a perforated semiconductor element, the probe being configured for passing therethrough a processing medium and for being insertable in the perforation in the semiconductor element, the probe comprising at least one outlet of said medium, to thereby supply said medium though said at least one output towards the inner surface of the perforated semiconductor element.

The processing medium may be liquid, gas, or certain radiation such as a light beam, a charged particles beam, or an X-ray.

According to yet another inventive aspect, there is provided a processing system for use in manufacturing at least one semiconductor device on an inner surface of a perforated semiconductor structure, the system being configured for supplying a selective processing medium, from a plurality of different media, into the perforation in the semiconductor element, the probe comprising an inlet arrangement including a valve assembly configured for selectively connecting a selective one of medium supply units, from a plurality of such units, to the perforation.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIGS. 1A and 1B schematically illustrate two examples, respectively, of a semiconductor device of the present invention;

FIGS. 2A and 2B schematically illustrate an integrated circuit of the present invention;

FIGS. 3A and 3B show a simple example of an integrated circuit of the present invention configured using a connecting ring between two annular chips;

FIGS. 4A to 4E show a central probe of the present invention suitable for manufacturing the integrated circuit of the present invention;

FIGS. 5A to 5C illustrate the principles of a bonding process;

FIG. 6 schematically illustrates another example of a probe device suitable to be used in the present invention; and

FIG. 7 illustrates a processing system of the present invention for use in manufacturing an integrated circuit of the present invention.

### DETAILED DESCRIPTION OF THE INVENTION

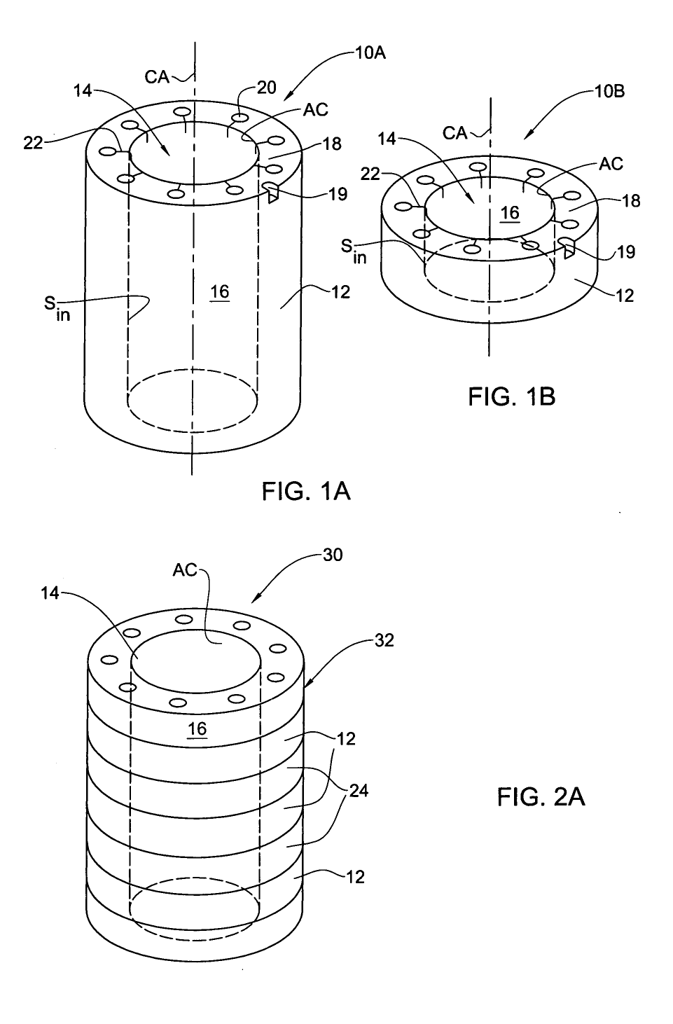

Referring to FIGS. 1A and 1B, there are schematically illustrated two examples, respectively, of an integrated semiconductor device or part thereof (generally, a chip) according to the invention. In the example of FIG. 1A, a device 10A has an elongated tubular-like configuration (its height is larger than its width), while in the example of FIG. 1B, a device 10B has a ring-like geometry (its height is smaller than its width). To facilitate understanding, the same reference numbers are used to identify common components in all the examples of the invention. These semiconductor devices are configured as annular chips AC.

The semiconductor device 10A (or 10B) includes a semiconductor element (wafer) 12 carrying electronic elements (features) of the semiconductor device, which are typically produced as a patterned area in the semiconductor element. The semiconductor element 12 has a through-going opening (perforation) 14 extending along a central axis CA thereof. This perforation forms a central channel 16 for producing a patterned area within an inner surface Sᵢₙ of the opening 14 to form the active surface of an annular chip AC. Although in the present examples the opening 14 has a circular cross section and the semiconductor element 12 has a ring-like cross-section, it should be understood that any other device configuration can be used, provided it defines a central channel for the formation of the device features on the inner surface of the opening 14. The central channel 16 is preferably of a circular cross section to thereby facilitate processing of the inner surface of the semiconductor element. As for the geometry of the external surface it may and not be circular (e.g., polygonal).

As further shown in FIGS. 1A-1B, a but-end surface 18 of the semiconductor element 12 is substantially flat and carries contact elements (pads), generally at 20. The contact pads 20 are arranged in an array on the surface 18 and are connected to the inner surface of the element 12 (i.e., to the annular chip AC) via conducting leads (wires), generally at 22, thus forming interconnects of the semiconductor device. The contact elements 20 may be made as grooves or holes containing an electrically conductive material. The leads 22 are located at the periphery region of the annular chip AC (ring). Also preferably provided on the surface 18 is an alignment mark 19 (typically termed “notch”) that is used for aligning the semiconductor element with respect to a processing tool.

The central channel 16 is a continuous hermetically sealed channel running from one end to the other. It serves for introducing processing media (different agents that are washed through, coat, act on, etch, implanted in, etc.) to the annular chip active surface, as well as for cooling the semiconductor device when in operation.

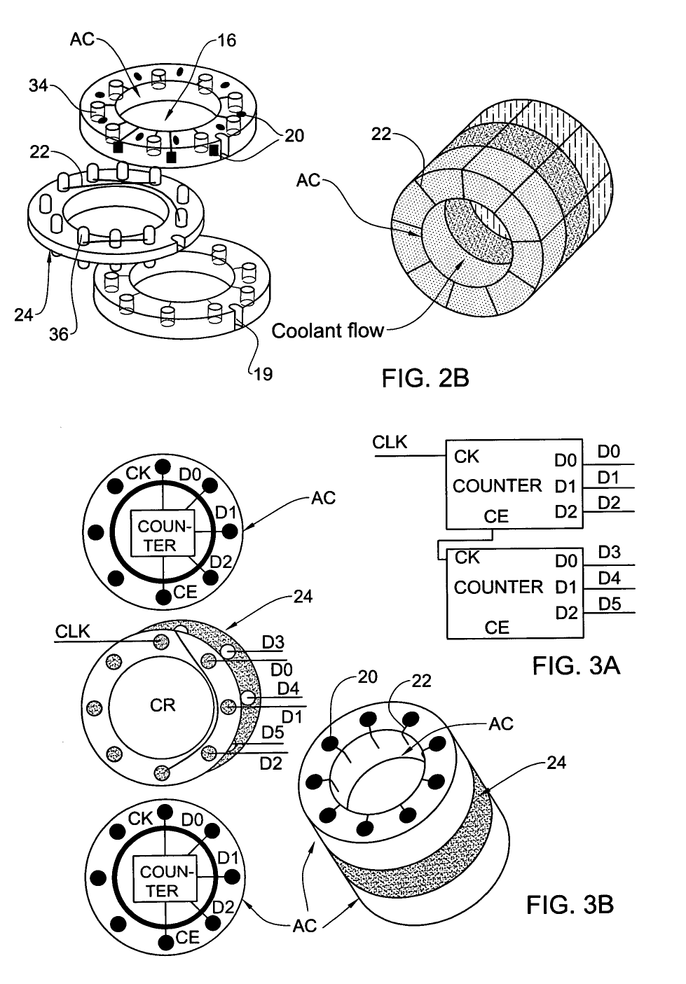

FIGS. 2A and 2B illustrate an electronic circuit 30 according to the invention formed by an array of annular chips AC. The circuit 30 has an elongated tubular-like semiconductor structure 32, which is formed by a plurality of ring-like semiconductor elements 12 arranged in a stack such that vertically aligned perforations 14 in the elements 12 form together a common channel 16. The semiconductor elements 12 carry annular chips AC of the electronic circuit 30, and may have similar or different patterns within the inner surfaces of the ring-like semiconductor elements 12. As better seen in FIG. 2B, the but-end substantially flat surfaces 18 of each semiconductor element 12 is patterned to form electrical contacts between the annular chips.

Generally, the electronic circuit 30 may be formed by separately processing inner surfaces of each of the semiconductor elements 12 to form annular chips AC and contact elements, and then assembling the so-produced annular chips in a stack. Preferably, however, the electronic circuit is prepared by stacking semiconductor elements 12, and then processing the inner surface Sᵢₙ of the entire tubular-like semiconductor structure 32 to form all the annular chips in a common lithography process via a common central channel 16.

It should be understood that the annular chips may and may not be identical. When manufacturing an integrated circuit, identical annular chips are stacked, and when building a complete circuitry of semiconductor devices, different types of annular chips are stacked one on top of the other.

The periphery regions of the annular chips AC may be formed with conducting leads 22 such that continuous lines run along the whole length of the stack. A typical integrated circuit may hold over 100 leads.

As shown in FIG. 2B, the periphery regions of the annular chips AC (rings) have conducting perforations 34 to enable direct annular chip to annular chip contacts in the stack using conducting rods 36 inserted into the conducting perforations 34. Preferably, however, each two locally adjacent annular chips AC of the integrated circuit 30 are connected to each other via a connecting ring-like device 24 located therebetween. The device 24 is a ring-like element that has no annular chip on its inner surface but has patterned flat surfaces 18 to form electrical connections. The connecting ring is a semiconductor or insulator made for example from one of the following materials: Silicon, GaAs, Sapphire, Quartz, Laminates, Glass, Ceramic. Such a perforated or specifically designed connecting ring 24 provides connection between the conducting leads 22 and the annular chips AC. The connecting rings have selected connections between the pads or conducting perforations so as to obtain the proper circuitry. Connecting rings thus establish connections between desired points of contact on two or more annular chips.

It should be noted that leads can run on the outer surface of the annular chip so as to have long connections in a stack of components. Wiring may be more efficient, lines do not cross, with the help of connecting rings (between annular chips) and shifting rings (from one position to another) one may not need to use tailor made printed circuits.

FIGS. 3A and 3B schematically illustrate in a self-explanatory manner a simple example of an electronic circuit built using a connecting ring 24 between two annular chips AC.

Comparing electronic circuits built from annular chips to those of conventional boards with microchips on them, the annular chips based circuit can be incorporated in devices having a different geometry, namely, as a stack of the annular chips. Per volume, annular stacks hold 2-3 times more chip surface area. The technique of the present invention allows for carrying out the entire manufacturing process in a long tube (in a long semiconductor element) and then cutting it into sub-units (ring-like annular chips).

Thus, the present invention provides for manufacturing the annular chip (FIGS. 1A and 1B) or an array of annular chips (FIGS. 2A-2C) by processing the inner surface of a ring-like or tubular-shape semiconductor element/structure. The processing is carried out via a central channel 16 defined by the opening(s) in the semiconductor element(s). The processing consists of patterning the inner surface in accordance with the features of the electronic circuits. Patterning typically includes material deposition and material removal processes, which may be carried out by a lithography tools arrangement including coating the surface by required materials (photoresist, etc.), exposure and developing; etching; polishing (CMP), etc. The material deposition may include chemical vapor deposition (CVD), physical vapor deposition (PVD), ion implantation, electroplating. The central channel is preferably hermetically sealed. The hermetic nature of the channel allows for flowing processing media (gases, liquids), controlling the flow, switching the flow, filling of the cavity, recycling, creating vacuum, etc. The processing is thus carried out in the sealed central channel 16.

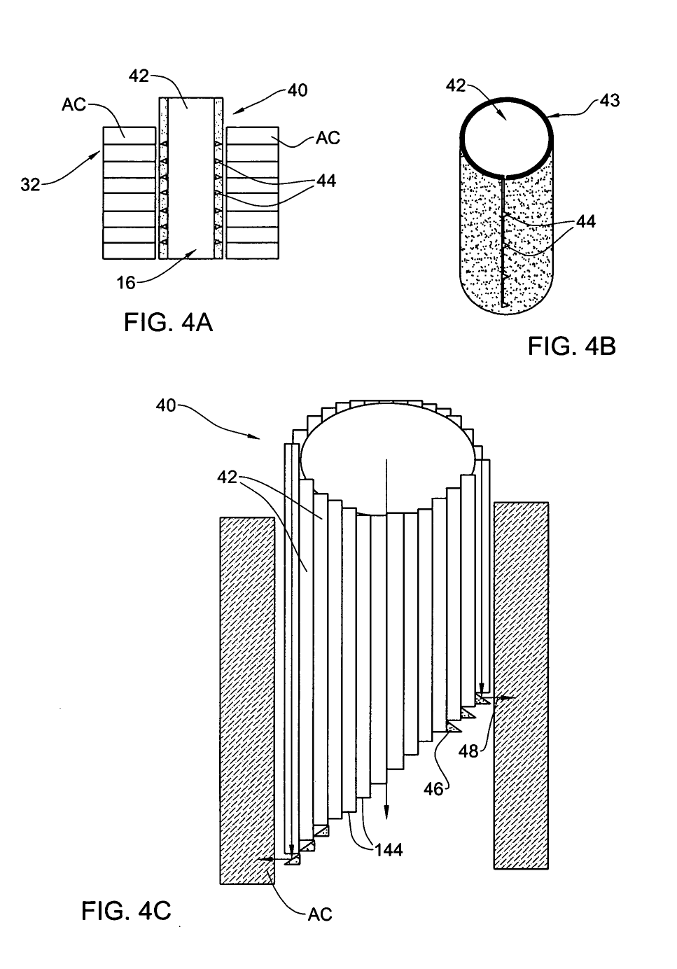

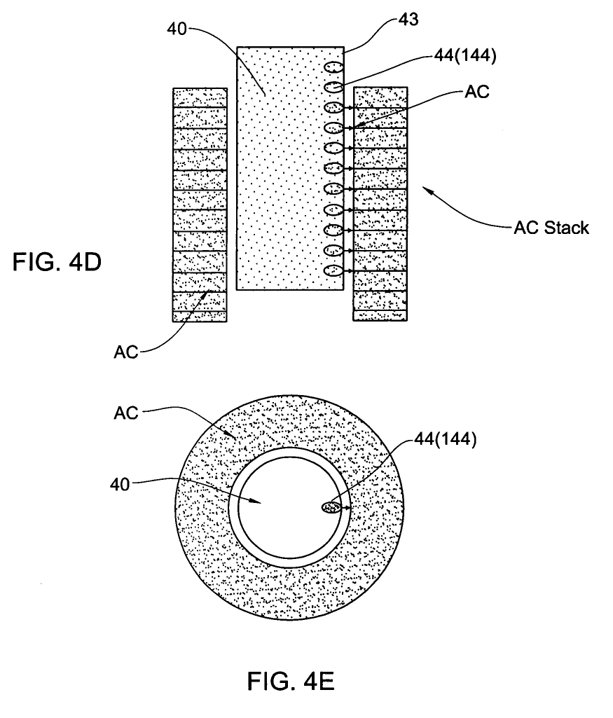

FIGS. 4A to 4D schematically illustrate the concept of the present invention of using a central probe 40 for processing the inner surface of a tubular-shaped semiconductor structure 32 to create annular chips AC of a certain electronic circuit. It should be understood that the same is relevant for processing a separate semiconductor element. The structure 32 is a stack of perforated semiconductor elements 12 defining a common central channel 16. The central probe 40 is positioned inside the central channel 16. The central probe 40 is basically a radiation conduit, which is configured as a single-channel conduit or multiple-channel conduit capable of transmitting therethrough radiation coming from a radiation source. The latter may be laser or other light emitting element (in which case the optical probe includes an optic fiber or a fiber bundle for transmitting visible and/or UV radiation), charged particles' beam source (e.g., electron beam source), or X-ray source.

In the example of FIG. 4B, an optical fiber 42 is used as a light conduit of the central probe. The fiber 42 has a special cladding 43, formed with “defects” such as perforations or “Spots”, generally at 44, which are anti-reflective surface regions of the cladding thus not reflecting the light that reaches the “spot” back into the fiber but allowing the light to be output from the fiber. The spot can be of a very small size, for example, the perforation 44 made by a focused laser beam can be under 1 micron. Preferably, the perforation 44 is shaped like a pore tunnel in the cladding (with the tunnel length larger than its diameter) to be therefore capable of forming a directional light beam, and not acting as a point-like light source illuminating in all the directions. Thus, while light propagates through the optical fiber 42 of the central probe 40, a beam of light is emitted from the spot 44. When the diameter of the central probe 40 is close to that of the central channel 16, the illuminated spot size on the inner surface of the semiconductor structure 32 is as small as the spot 44, i.e., in the order of or under one micron. Spots 44 are arranged in a spaced-apart relationship along the axis of the probe, being spaced from each other a distance equal to the distance between corresponding points (similar features) on the adjacent annular chips AC in the stack. Thus, at any current position of the central probe 40 inside the central channel, the spots 44 simultaneously illuminate a plurality of points on the inner surface of the semiconductor structure, e.g., corresponding points on all the annular chips AC in the stack. The spots 44 may be arranged in accordance of the desired pattern to be obtained, thus patterning consists of flashing light pulses through the spots 44 to draw the desired pattern.

The optical fiber may include a single spot 44 or plurality of such spots, the patterning being carried out by providing a relative displacement between the semiconductor structure and the probe located in the central channel. The relative displacement includes a relative rotation and relative back and forward movement. As a result, at any current position of the probe relative to the semiconductor structure, at least one spot 44 is positioned opposite a predetermined point on the inner surface of the semiconductor structure. Preferably, the probe is rotated with respect to the semiconductor structure and possible also moved along the axis of the central channel. It should be understood that the processing is managed by a control system connectable to the radiation source and to a drive mechanism responsible for the relative movement between the central probe and the semiconductor structure, and operable to provide synchronization between the rotation and the light flashing.

As shown in the example of FIG. 4C, the central probe 40 includes an array of fibers, generally at 42′, the number of fibers in the array corresponding to the number of annular chips AC in the stack, or a substantial fraction thereof. The distal ends 144 of the fibers inside the central channel 16 are spaced-apart from each other, such that each fiber terminates at the level of the corresponding annular chip. A light directing optical element 46, such as a mirror or prism, is located at the distal end of each of the fibers 42, to direct a respective light beam 48 exiting the fiber towards the inner surface of the stack (i.e., direct the beam at 90 degrees relative to the fiber axis). The spots or perforations 44 in the fiber cladding (FIG. 4B) or distal ends 144 of the fibers 42′ (FIG. 4B) constitute lighting elements.

FIGS. 4D and 4E illustrate the general concept of using the central probe 40 in the central channel 16 for processing the inner surface of the semiconductor structure. The central probe 40 has a radiation conduit 43 carrying an array of radiation (e.g., lighting) elements 44 (or 144) arranged in a spaced-apart relationship along the axis of the central channel. The central probe 40 can be rotated rapidly along its axis relative to the annular chip stack (or the annular chip stack can spin around the stationary mounted central probe 40. In this case, if optic fibers are used, the lighting element 44 (or 144) can be separated by a small gap from the light conduit 43 that is equipped with a proper optic coupler. Generally, such illumination is a near-field illumination. An annular aperture, such as a pinhole mirror or a corresponding small diameter tube, may be accommodated in the optical path of each light beam to thereby even more reduce the spot size. If illuminated continuously, during the rotation of the central probe or the annular chip stack, the central probe illuminates a line on the all corresponding locations in the stacked annular chips. If the central probe illumination is in pulses, the annular chip illumination will be in spots of a size determined by the light beam cross section (the diameter of spot 44 in FIG. 4B or the distal end 144 of the fiber in FIG. 4C), and the flash duration and speed of rotation. Thus, at a given speed of rotation, that can be computer controlled, by computer controlled flashing, one can “draw” any illumination pattern along the line on the annular chip surface. After completing a full “illuminating” rotation, the central probe is pulled-pushed by a selected step to the next position to be acted upon on the annular chip and the rotation-flashing process is repeated. This process is repeated until all the necessary annular chip area (covered by the photoresist, etc.) is illuminated, as if it was illuminated through a mask. This technique actually presents Virtual Lithography using “Soft Masks”.

The central probe can consist of more than one fiber with cladding pores so that it can simultaneously flash a number of spots on different locations. This would also increase the energy per spot. This energy can be further enhanced by placing mirrors or prisms at the distal ends of the fibers to reflect the light back and forth. The central probe may include a number of fibers corresponding to the number of annular chips in the stack, each fiber terminating at the level of the corresponding annular chip with a mirror or prism that points the exiting light beam 90 degrees relative to the fiber axis. The central probe can move-rotate in a spiral manner relative to the annular chip stack and thus advance both along the circumference and the long axis of the stack.

As indicated above, the illuminated spot size can be of about 1 micron or even lower. A relative displacement between the central probe and the annular chip stack (by moving either one of them or both up and down along the central axis CA) may be provided using a motorized micromanipulator (not shown) with a resolution better than 0.01-0.1 micron. Therefore, the system resolution can be in the order of 0.1 micron or better.

For example, a typical large annular chip stack may have a central channel measuring 6 mm in diameter, i.e., may have a circumference of about 20 mm, a length of 5 mm and an area of 100 mm² or 0.1 cm². For a resolution of 2 micron, each line on the annular chip stack must have 10000 spots, and the whole annular chip having about 3000 lines. If the central probe (or the annular chip stack) turns at a rate of 100 revolutions per second, time to complete a full turn and to move from one line to the next is about 10 ms. The rotation is preferably made by means of a step motor under computer control. Rotation resolution can be enhanced by a gear mechanism. Acting on the whole annular chip would take 30 seconds, and as the process is being carried out in parallel on the whole stack containing, for example, 500 annular chips, the building of 20 layers would take about 6 minutes. Processing with a 0.2 micron resolution will require about 1 hour. This is very favorably in comparison with the current duration of processing with a mask, excluding the lengthy process of generating the masks.

Under these conditions, the duration of each light flash is of about 0.5 microseconds and the flashing rate is about 10⁶/sec, all achievable under computer control, for example, by laser diodes or flash lamps. Such a Soft Mask can be readily constructed, modified, corrected, etc. virtually on line.

It should be noted that the duration of the virtual lithography can be significantly faster than the conventional one. As the spot writing is virtually of contact print nature, it may be possible to achieve resolutions far better than 1 micron.

When each annular chip AC is a separate semiconductor device, the semiconductor ring (e.g. silicon, GaAs, etc.) it is formed on can be prepared with contact pads on its outer flat surface (or any other surface) and with leads leading to pre-selected points on the active annular chip surface (inner surface of the ring). The leads can be manufactured on the surface by conventional means including printed circuit methods and standard microelectronics. The annular chip circuit makes proper contacts with the leads by bonding.

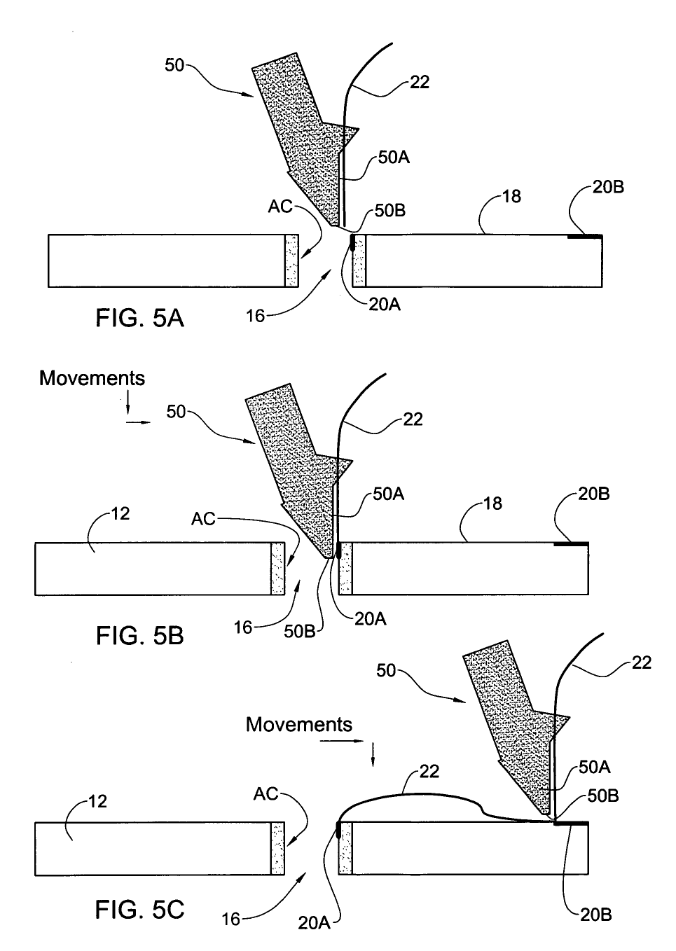

The bonding can be made by the central probe in a stack. One of the differences between the conventional microchips manufacturing technique and that of the present invention is the fact that according to the invention perforated semiconductor elements are generally pre-cut. Hence, contact elements (pads, legs, etc.) can be pre-positioned on the semiconductor elements before the patterning. These can be implemented, for example, by simple plating or printed circuit technologies. Contact points can be on the flat surfaces or the ring-like circumference. If these contact points have an extension towards the inner channel, patterning can establish proper contacts with them during the fabrication process. This is illustrated in FIGS. 5A-5C.

A bonding wedge tool 50 has two bonding surfaces—a side bonding surface 50A and a bottom bonding surface 50B. As shown in FIGS. 5A and 5B, initially the wedge bonds a wire 22 (e.g., Ai or Au) to a pad 20A which is part of the circuit made on the inner surface Sᵢₙ of the central channel 16. This is implemented by means of the side bonding surface 50A, while the wedge tool 50 is moved to be inserted into the channel 16 of an individual unit AC. As shown in FIG. 5C, the second bond is made by bonding the continuation of the wire 22 to a pad 22 on the flat surface 18 (or the circumference or a package into which the rings is integrated). This is made by either one of the side and bottom bonding surfaces 50A and 50B, depending on the orientation of the pad surface.

Thus, according to the invention, the annular chip based circuit can be produced by direct photo-lithography using the central probe and without the use of masks. Rather, a computer controlled laser or some other light source is used to shine light only at the desired locations on the annular chip surface, or a number of light sources is used. The inner surface of the perforated semiconductor structure is coated by required materials (photoresist, etc.), then the central probe is positioned in the central channel, and exposes to light selective locations on the inner surface.

As indicated above, in the annular chip based manufacturing, all the processes involving the use of fluids/liquids, or gases, that make contact with the chip are carried out by the flow of the fluid in the central channel. In this case, the annular chip stack is stationary mounted, while fluids can be changed by switching of flows, etc. Rapid flow rates can be very effective in cleaning. Saving in quantities of required chemicals or other materials can be significant due to the relatively small volumes needed, in contrast to the conventional baths, and can be further improved by recirculation and possibly filtration. Drying can be achieved by either flushing air or gas or creating vacuum in the central channel. It is much easier and quicker to create vacuum in the central channel tubing. It should also be noted, although not specifically shown that the probe can carry along its shaft such processing and/or monitoring parts as heating elements, sensors (flow, temperature, etc) that check the performance during fabrication and after its completion to ensure optimal results. Inspection/monitoring of the processing may include optical means applied via the central channel, and analyzing measured data by image processing based on pattern recognition.

To implement thermal processing, the annular chip based technique of the present invention provides for fast and simple heating by means of the flow of gas or liquid through the central channel (rather than placing wafers in an oven, as in the conventional technique). The flow can be in the central channel itself, or through a metal tube running along the central channel. Efficient cooling can also be achieved in a similar manner.

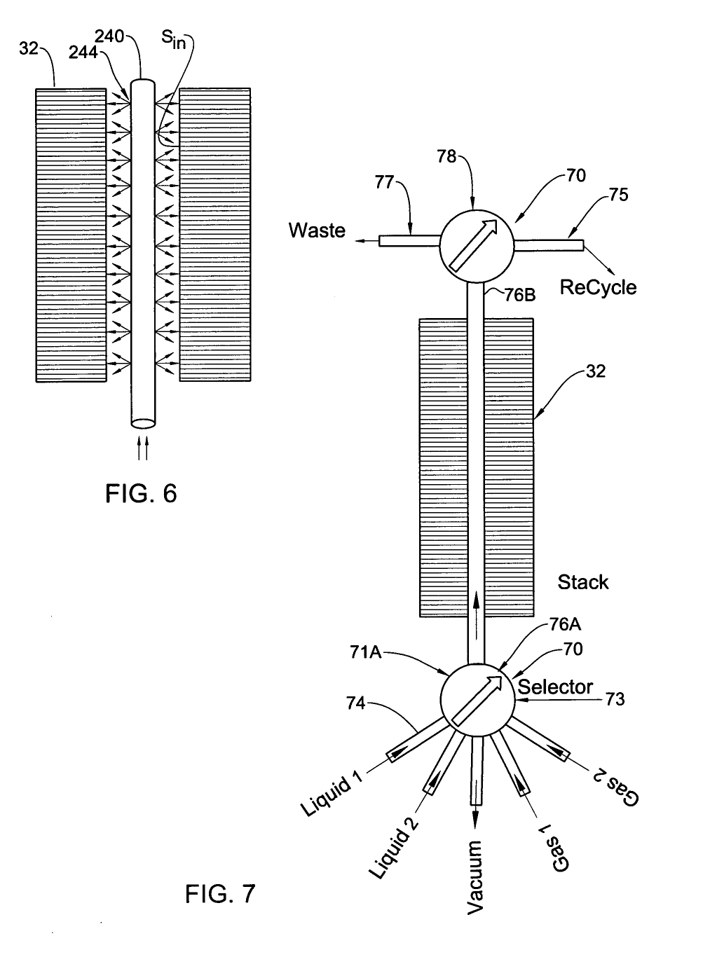

It should be noted that a central probe substantially smaller in diameter than that of the central channel can be used for example for spraying all along the channel. This is illustrated in FIG. 6. A central probe 240 of a smaller diameter than the central channel 16 of a semiconductor structure 32 is located inside the central channel 16. The semiconductor structure 32 in the present example is in the form of a stack of perforated semiconductor elements 12 (preferably spaced by connecting rings), but it should be understood that a single tubular-shaped semiconductor element may be processed in a similar way. The central probe 240 is formed with a plurality of spaced-apart outlet openings (perforations), generally at 244. The perforations 244 are arranged in accordance with a pattern of spaced-apart regions to be sprayed on the inner surface Sᵢₙ of the semiconductor structure 32. An open end 246 of the probe located outside the central channel serves as an inlet for a spraying medium. The latter, while flowing through the probe is output through the perforations 244. The open end 246 of the probe may be connected to a plurality of supply units, each for supplying a different spray. This connection is implemented via a selector arrangement, which is actually a valve arrangement selectively connecting a respective one of the supply units to the probe.

FIG. 7 exemplifies how the present invention allows for selectively supplying a required processing medium from a plurality of different such mediums into a central channel 16 in automatic manner. In the present example of FIG. 7, a “free” central channel (with no probe extending along the central channel) is considered, and processing mediums are passed through the “open” central channel. It should, however, be understood that the concept of using a selector 72 interconnected between an array of supply units, generally at 74, and the inlet of the central channel can be used as well with the central probe located inside the central channel. Thus, in the present example, a processing system 70 is configured for flowing a selected processing medium (liquid or gas) through the central channel 16. The processing system 70 includes an inlet arrangement 71A accommodated at one side of the central channel, and an outlet arrangement 71B accommodated at the other side of the central channel.

The inlet arrangement 71A is configured for supplying at least one selected medium, from a plurality of different mediums, into the channel 16. To this end, the inlet arrangement 71A includes a valve assembly 73 (the so-called “selector) connectable to the plurality of supply units, generally at 74, and connectable to an inlet tube-like member (pipe) 76A extending between the valve arrangement 73 and the central channel 16. The pipe 16 is preferably of a diameter substantially equal to that of the central channel. The valve assembly 73 is operated by a control system (not shown) to selectively establish connection between the selected supply unit 74 and the pipe 76A.

The outlet arrangement 71B is configured for flowing the processing medium away from the central channel 16 towards either one of a recycle channel 75 and a waste channel 77. The outlet arrangement 71B includes a valve assembly 78, which is connected to an outlet pipe 76B that extends between the valve 78 and the central channel 16 and that is preferably of a cross sectional size equal to that of the central channel; and is connectable to recycling and waste channels 75 and 77. The valve assembly 78 is operated by the control system to selectively establish connection between the outlet pipe and the selected one of recycling and waste channels.

The advantages of the present invention are self-evident. The finished integrated circuits, manufactured as annular chips can be packaged in the current standard rectangular formats and serve in the current technologies, or in ring format. Such ring-like chips can be stacked and intermixed with specially designed connection rings to form complete circuitry. A relatively small number of differently configured connecting rings can support practically all types of circuits such that building a device can resemble Lego construction without the need for printed circuitry. Due to the semi-3D stricture of the stacked annular chips, devices built therefrom occupy smaller total volumes as compared to circuits built on Boards, etc. The central canal provides a superb means for cooling the devices. The tubular structure with a central tunnel enables easy electromagnetic shielding.

Those skilled in the art will readily appreciate that various modifications and changes can be applied to the embodiments of the invention as hereinbefore exemplified without departing from its scope defined in and by the appended claims.

1. A method for manufacturing an integrated semiconductor device, the method comprising: providing a semiconductor element having a perforation extending along a central axis of said element, thereby defining a central channel inside said element; and processing an inner surface of said perforation via the central channel to form features of the semiconductor device to be manufactured on said inner surface.

2. The method of claim 1, wherein the processing comprises patterning said inner surface in accordance with the features of the semiconductor device.

3. The method of claim 1, wherein the processing comprises applying to said inner surface material deposition and material removal processes.

4. The method of claim 1, wherein the processing comprises applying to said inner surface a lithography process.

5. The method of claim 1, wherein the processing comprises applying to said inner surface an etching process.

6. The method of claim 1, wherein the processing comprises applying to said inner surface a surface polishing process.

7. The method of claim 3, wherein the material deposition process includes a chemical vapor deposition.

8. The method of claim 3, wherein the material deposition process includes a physical vapor deposition.

9. The method of claim 3, wherein the material deposition process includes electroplating.

10. The method of claim 3, wherein the material deposition process includes ion implantation.

11. The method of claim 3, wherein the material removal process includes etching.

12. The method of claim 3, wherein the material removal process includes chemical mechanical polishing.

13. The method of claim 1, wherein said processing comprises supplying processing media into the sealed central channel.

14. The method of claim 1, wherein said processing comprises flowing processing media through the central channel.

15. The method of claim 1, wherein said processing comprises locating a central probe in said central channel so as to extend along the central channel.

16. The method of claim 15, wherein said central probe has a cross section substantially identical to that of said perforation.

17. The method of claim 15, wherein said central probe has a cross section substantially smaller than that of said perforation.

18. The method of claim 15, comprises providing a relative displacement between the central probe, while in said perforation, and the semiconductor element.

19. The method of claim 18, wherein the relative displacement comprises revolution of at least one of the central probe and the semiconductor element about said central axis.

20. The method of claim 18, wherein said relative displacement comprises back and forward movement of at least one of the central probe and the semiconductor element along said axis.

21. The method of claim 15, wherein said central probe has a plurality of perforations for supplying therethrough a processing medium towards the inner surface of the semiconductor element.

22. The method of claim 15, wherein said central probe has a radiating element, the method comprising providing a relative displacement between the central probe and the semiconductor element to thereby apply radiation to a plurality of locations on said inner surface.

23. The method of claim 22, comprising synchronizing the relative displacement and the operation of the radiation element.

24. The method of claim 15, wherein said central probe has a plurality of radiating elements arranged in a spaced-apart relationship along an axis parallel to the central axis to thereby apply radiation to spaced-apart locations on said inner surface.

25. The method of claim 24, wherein the spacing between the radiating elements corresponds to a spacing between two locally adjacent semiconductor elements.

26. The method of claim 22, wherein the radiating element is configured for generating one of the following: a light beam, an electron beam, an X-ray.

27. The method of claim 24, wherein the radiating element is configured for generating one of the following: a light beam, an electron beam, an X-ray.

28. The method of claim 24, wherein the central probe comprises an optical fiber having a plurality of perforations or spots in its cladding layer, said perforations or spots being arranged in the spaced-apart relationship thus presenting said plurality of radiating elements, respectively.

29. The method of claim 24, wherein the central probe comprises a plurality of optical fibers accommodated such that their distal ends are arranged in the spaced-apart relationship thus presenting said plurality of radiating elements, respectively.

30. The method of claim 24, comprising passing a plurality of light beams propagating through said radiating elements towards said locations through light directing elements, respectively.

31. The method of claim 30, wherein the light directing element includes an annular aperture.

32. The method of claim 29, comprising a plurality of light directing elements located at the distal ends of the fibers, respectively.

33. The method of claim 32, wherein each of the light directing elements directs a light beam existing from the respective distal end along an axis oriented at 90 degrees to the fiber axis.

34. The method of claim 32, wherein the light directing element includes an annular aperture.

35. The method of claim 1, wherein said semiconductor element has the substantially circular perforation.

36. The method of claim 1, wherein said semiconductor element has a ring-like cross section.

37. The method of claim 1, wherein said semiconductor element is a stack of coaxially aligned sub-elements, each having a substantially planar surface by which it faces the adjacent sub-element and having the perforation, the coaxially aligned perforations defining the common central channel.

38. The method of claim 1, comprising providing contact elements on a butt-end substantially flat surface of the semiconductor element.

39. The method of claim 38, wherein the contact elements are made as perforations in said butt-end substantially flat surface for containing an electrically conductive material.

40. The method of claim 38, comprising providing conducting leads between the contact elements and said inner surface of the semiconductor element.

41. The method of claim 37, comprising configuring some of the sub-elements so as to be a connecting sub-element for its two adjacent sub-elements.

42. The method of claim 41, wherein the connecting sub-element is a semiconductor or insulator.

43. The method of claim 41, wherein the connecting sub-element has an array of perforations in its substantially flat surfaces for connecting said two adjacent sub-elements to each other through said perforations in the connecting sub-element.

44. An integrated semiconductor device manufactured by the method of claim 1.

45. An integrated semiconductor device comprising a semiconductor element having a perforation extending along a central axis of said element, an inner surface of said perforation being patterned in accordance with features of the semiconductor device.

46. The device of claim 45, being configured such that its height is smaller than its width.

47. The device of claim 45, wherein said perforation has a substantially circular cross section.

48. The device of claim 45, wherein said semiconductor element has a substantially ring-like cross section.

49. The device of claim 45, wherein said semiconductor element has contact elements on its but-end substantially flat surface.

50. The device of claim 49, wherein said contact elements are configured as perforations in said but-end substantially flat surface for containing an electrically conductive material.

51. The device of claim 50, comprising conducting leads connecting said contact elements to said inner surface of the semiconductor element.

52. The device of claim 45, comprising a stack of coaxially aligned sub-elements, each having a substantially planar surface by which it faces the adjacent sub-element and having the perforation, the perforations of said sub-element being coaxially aligned to define a common inner channel of the device.

53. The device of claim 45, comprising an alignment mark.

54. The device of claim 53, wherein the alignment mark is located on an outer surface of the semiconductor element.

55. The device of claim 45, comprising a cooling channel constituted by said perforation.

56. An electronic circuit comprising at least two semiconductor devices, each configured as the device of claim 45, said at least two semiconductor devices being coaxially mounted in a stack, each of the semiconductor devices having a substantially planar surface by which it faces the adjacent device.

57. The circuit of claim 56, wherein said at least two semiconductor devices have different features.

58. The circuit of claim 56, comprising a cooling channel constituted by said perforation.

59. An integrated circuit comprising a semiconductor structure in the form of a plurality of perforated semiconductor elements arranged such that the perforations in the elements are aligned along an axis of the stack thereby defining a common perforation extending along the stack, an inner surface of said common perforation being patterned in accordance with features of the integrated circuit.

60. An integrated semiconductor device comprising a ring-like semiconductor element, an inner surface of said ring-like element being patterned in accordance with features of the semiconductor device.

61. An electronic circuit comprising a stack of ring-like semiconductor elements aligned along a central axis of the stack, an inner surface of the stack being patterned in accordance with features of the electronic circuit.

62. A method of manufacturing a ring-like semiconductor device, the method comprising providing a ring-like semiconductor element; and applying a lithography process to an inner surface of the ring like semiconductor element to thereby define features of the semiconductor device.

63. A probe for use in manufacturing a semiconductor device on an inner surface of a perforated semiconductor element, the probe being configured for passing therethrough a processing medium and for being insertable in the perforation in the semiconductor element, the probe comprising at least one outlet of said medium, to thereby supply said medium though said at least one output towards the inner surface of the perforated semiconductor element.

64. The probe of claim 63, wherein said medium is liquid.

65. The probe of claim 63, wherein said medium is gas.

66. The probe of claim 53, wherein said medium is certain radiation.

67. The probe of claim 66, wherein said certain radiation includes one of the following: a light beam, a charged particles beam, an X-ray.

68. The probe of claim 63, comprising the single outlet, a relative displacement between said probe and said semiconductor element resulting in that said medium is supplied to spaced-apart locations on said inner surface.

69. The probe of claim 63, comprising a plurality of said outlets arranged in a spaced-apart relationship along the probe, thus allowing for supplying said medium to spaced-apart locations on said inner surface.

70. An optical probe for use in manufacturing at least one semiconductor device on an inner surface of a perforated semiconductor structure, the probe having a tubular geometry of a diameter so as to be insertable in the perforation in the semiconductor element, and comprising a plurality of radiating elements arranged in a spaced-part relationship along the probe, the probe being operable to irradiate spaced-apart locations on the inner surface of the perforated semiconductor element.

71. The probe of claim 70, comprising an optical fiber having a plurality of perforations or spots in its cladding layer, said perforations or spots being arranged in the spaced-apart relationship thus presenting said plurality of radiating elements, respectively.

72. The probe of claim 70, comprising a plurality of optical fibers accommodated such that their distal ends, to be located inside said perforation in the semiconductor element, are arranged in the spaced-apart relationship thus presenting said plurality of radiating elements, respectively.

73. The probe of claim 70, wherein the spacing between the radiating elements corresponds to a spacing between two adjacent perforated semiconductor elements in a stack of semiconductor elements forming said semiconductor structure.

74. The probe of claim 70, comprising a plurality of light directing elements, each accommodated in a path of a light beam coming from the respective one of said radiating elements.

75. The probe of claim 74, wherein the light directing element includes an annular aperture.

76. The probe of claim 72, comprising a plurality of light directing elements located at the distal ends of the fibers, respectively, each of the light directing elements directing a light beam existing from the respective distal end along an axis oriented at 90 degrees to the fiber axis.

77. A processing system for use in manufacturing at least one semiconductor device on an inner surface of a perforated semiconductor structure, the system being configured for supplying a selective processing medium, from a plurality of different media, into the perforation in the semiconductor element, the probe comprising an inlet arrangement including a valve assembly configured for selectively connecting a selective one of medium supply units, from a plurality of such units, to the perforation.

78. The system of claim 77, configured for flowing the processing medium through the perforation in the semiconductor structure, the system comprising an outlet arrangement accommodated at other side of the perforation opposite to the inlet arrangement and comprising a valve arrangement configured for selectively connecting the inside of said perforation towards either one of medium recycle and waste channels.
